(19) United States
(12) Patent Application Publication
(10) Pub. No.: US 2010/0020487 A1
(43) Pub. Date: Jan. 28, 2010

(54) AIRFLOW CONDUCTING APPARATUS

(75) Inventors: SHENG-HUNG LEE, Tu-Cheng (TW); LI-PING CHEN, Tu-Cheng (TW); XIU-ZHONG YIN, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/208,665

(22) Filed: Sep. 11, 2008

(30) Foreign Application Priority Data
Jul. 23, 2008 (CN) 200820301574.2

(51) Int. Cl. H05K 7/20

(52) U.S. Cl. 361/679.49

(57) ABSTRACT

An airflow conducting apparatus is used for dissipating heat from at least one memory module received in a corresponding socket on a motherboard. The airflow conducting apparatus includes an airduct and a valve piece. The airduct is positioned over the socket and configured to guide air to flow therethrough. The valve piece is attached to an inside of the airduct. The valve piece includes a plurality of parallel elastic flaps. Each flap has at least one configuration that deflects air flowing through the airduct.

### BACKGROUND

1. Technical Field

The present invention relates to an airflow conducting apparatus and, more particularly, to an airflow conducting apparatus for dissipating heat from memory modules of a computer.

2. Description of Related Art

An airflow conducting apparatus is usually used in a computer or server to dissipate heat generated from heat generating elements. A typical airflow conducting apparatus used to guide airflow generated from a fan, includes a frame body enclosing the fan, and a cover defining a through passage way.

In practical applications, when the typical airflow conducting apparatus is used to dissipate heat from memory modules of a computer, the number of used memory modules is uncertain. Drawing heat away from areas where there are no memory modules is a waste of airflow efficiency in the airflow conducting apparatus.

Therefore, a new airflow conducting apparatus is desired to overcome the above-described shortcoming.

### BRIEF DESCRIPTION OF THE DRAWINGS

FIG. 1 is an exploded isometric view of one embodiment of an airflow conducting apparatus for memory modules on a motherboard, the airflow conducting apparatus includes an airduct and a valve piece.

FIG. 2 is an assembled isometric view of the airflow conducting apparatus of FIG. 1, shown without the airduct.

FIG. 3 is an assembled isometric view of the airflow conducting apparatus of FIG. 1.

FIG. 4 is an assembled isometric view of the airflow conducting apparatus of FIG. 3, but viewed from another aspect.

### DETAILED DESCRIPTION OF THE EMBODIMENTS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

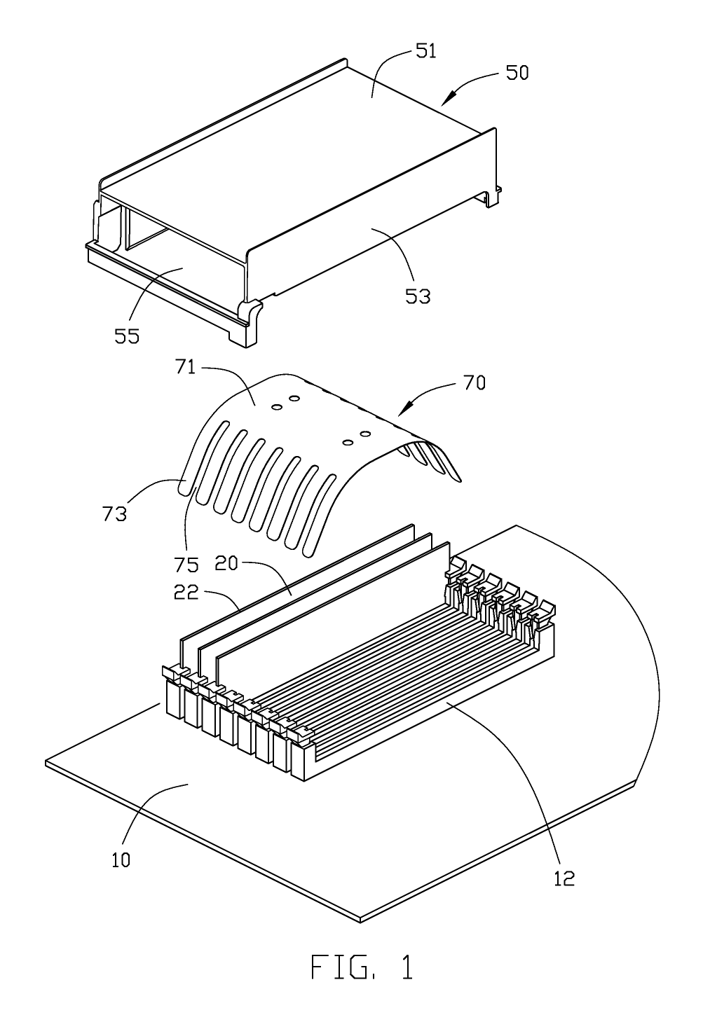

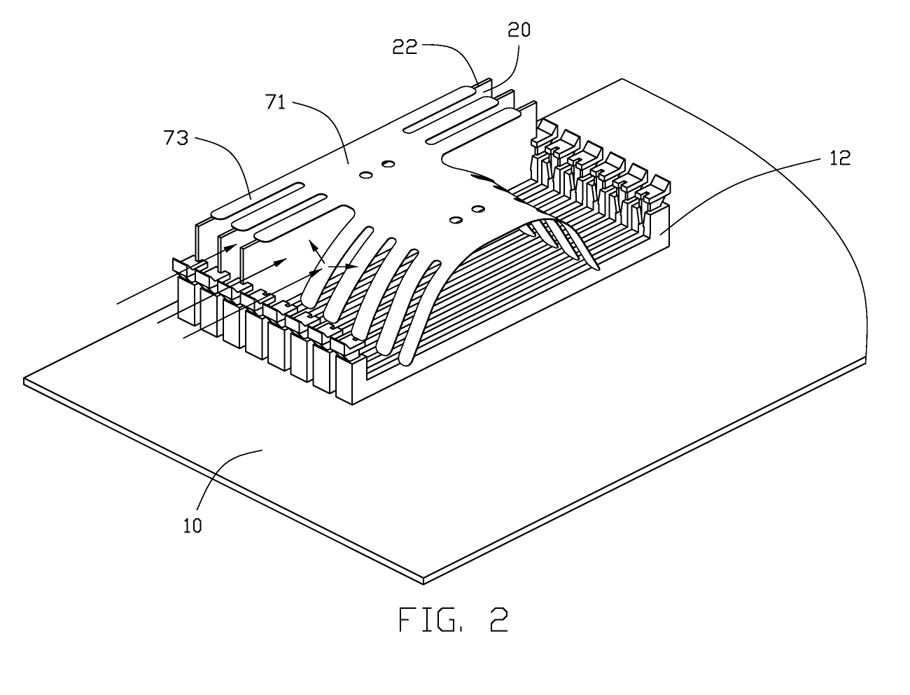

Referring to FIG. 1, one embodiment of an airflow conducting apparatus, configured to guide airflow (indicated by direction arrows in FIG. 2) to dissipate heat from a plurality of memory modules 20 on a motherboard 10. The airflow conducting apparatus includes an airduct 50 and an adjustable valve piece 70. The motherboard 10 includes a plurality of sockets 12 to receive the memory modules 20. Each memory module 20 includes a top surface that partially supports the adjustable valve piece 70 when the adjustable valve piece 70 is coupled to the motherboard 10.

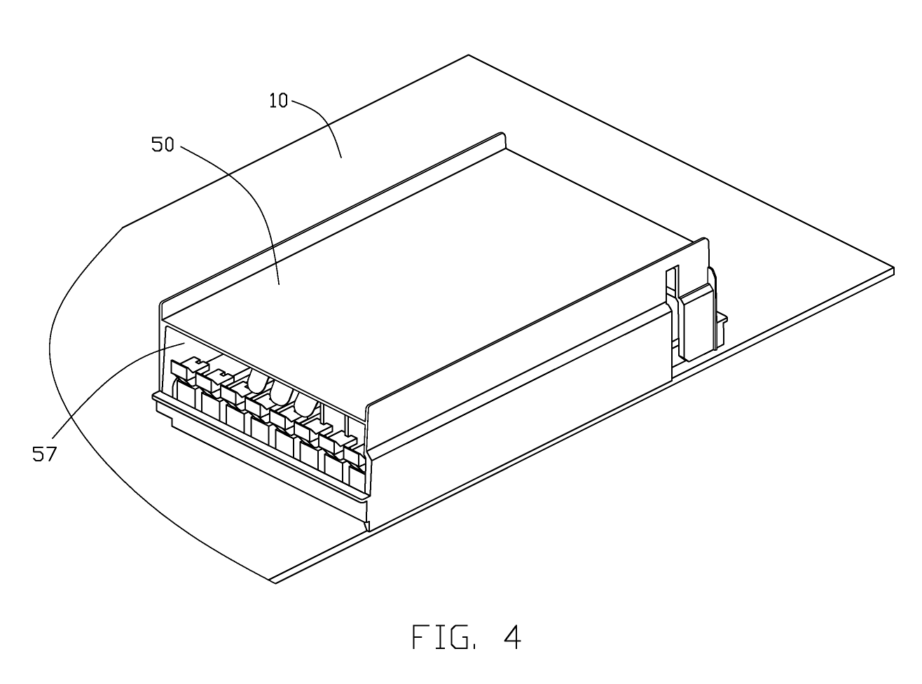

The airduct 10 includes a top wall 51, and a pair of side walls 53 extending perpendicularly from the top wall 51. The top wall 51 and the side walls 53 cooperatively define an airflow passage. An inlet 55 and an outlet 57 (as shown in FIG. 4) are defined on opposite sides of the airduct 50 to communicate with the airflow passage.

The valve piece 70 may be flake shaped. The valve piece 70 includes a body 71 and a plurality of parallel elastic flaps 73 extending from opposite sides of the body 71. A gap 75 is defined between adjacent flaps 73. The valve piece 70 is configured to have an arched shape with the flaps 73 on each side of the valve piece 70 curving at substantially the same curvature. A width of each flap 73 is larger than a width of the top surface of each memory module 20.

Referring to FIG. 2, the airduct 50 is omitted to clearly illustrate the one embodiment of the airflow conducting apparatus. The body 71 is mounted to an inner surface of the top wall 51 of the airduct 50 in a manner such that the flaps 73 extends outwardly. A number of memory modules 20 are coupled in the corresponding sockets 12. The sockets 12 are covered by the airduct. A first group of the flaps 73 that are aligned with the memory modules 20 abut the memory modules 20 and becomes flattened between the top surface of the memory modules 20 and the top wall 51. A second group of the flaps 73 that are not aligned with the memory modules 20, substantially remain the same shape and extend towards the sockets 12 without the memory modules 20.

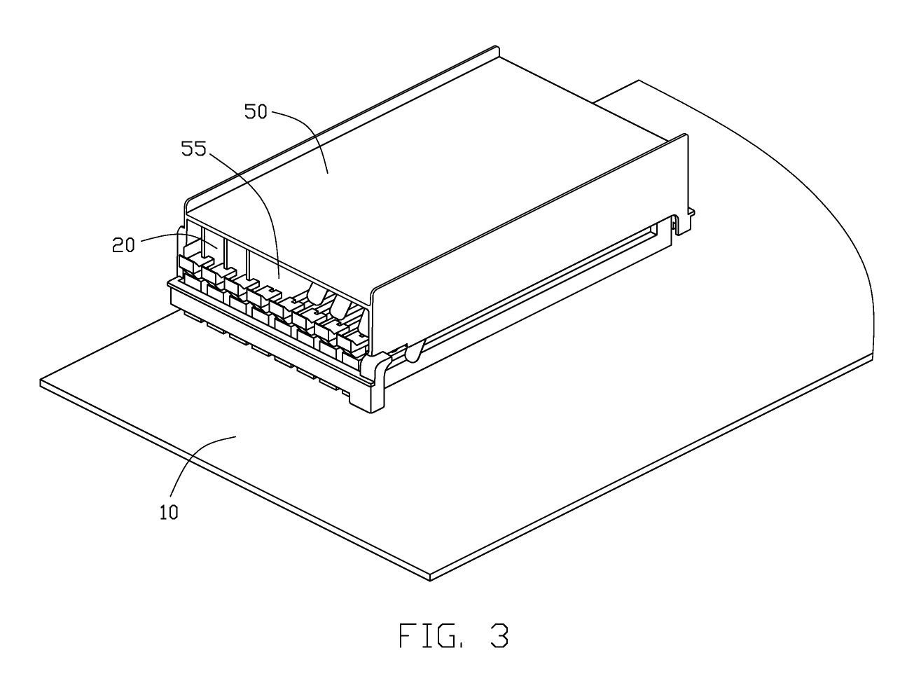

Referring also to FIG. 3 and FIG. 4, when using the airflow conducting apparatus to dissipate heat from the memory modules 20, the airflow is guided into the airduct 50 via the inlet 55. When the airflow travels to the memory modules 20, the airflow dissipates heat from the memory modules 20. When the airflow travels to the sockets 12 without the memory modules 20, the airflow is partially deflected by the curved flaps 73 towards the memory modules 20 to enhance the heat dissipating efficiency. Therefore, the airflow conducting apparatus efficiently uses the airflow to dissipate heat from the memory modules 20.

It is to be understood, however, that even though numerous characteristics and advantages of the present embodiments have been set forth in the foregoing description, together with details of the structure and function of the embodiments, the disclosure is illustrative only, and changes may be made in detail, especially in matters of shape, size, and arrangement of parts within the principles of the embodiments to the full extent indicated by the broad general meaning of the terms in which the appended claims are expressed.

What is claimed is:

1. An airflow conducting apparatus for dissipating heat from at least one memory module received in a corresponding socket on a motherboard, the airflow conducting apparatus comprising:
an airduct positioned over the socket and configured to guide air to flow therethrough; and
a valve piece attached to an inside of the airduct, the valve piece comprising a plurality of parallel elastic flaps, each flap having at least one configuration that deflects air flowing through the airduct.

2. The airflow conducting apparatus of claim 1, wherein each flap is aligned with the socket upon the condition that the at least one memory module is installed in the corresponding socket, the corresponding flap is deflected by a top surface of the corresponding memory module.

3. The airflow conducting apparatus of claim 1, wherein a width of each flap is larger than a width of a top surface of each memory module.

4. The airflow conducting apparatus of claim 1, wherein the flaps extends from opposite sides of the valve piece.

5. The airflow conducting apparatus of claim 4, wherein the valve piece is arcuate shaped at an original state configuration; each flap curves towards the sockets in the original state configuration.

6. The airflow conducting apparatus of claim 1, wherein the airduct comprises a top wall and a pair of side walls extending perpendicularly from the top wall; the valve piece is attached to an inner surface of the top wall.

7. The airflow conducting apparatus of claim 1, wherein each flap has a flake shape.

8. A computer comprising:
a motherboard comprising a socket arranged along a first direction;
a memory module received in the socket; and
a valve piece comprising a first elastic flap, the first flap positioned at a lateral side of the memory module having at least one configuration that deflects air flowing along the first direction towards the memory module.

9. The computer of claim 8, wherein the valve piece further comprises a second flexible flap having at least one configuration that deflects air flowing along the first direction towards the memory module; the second flap is deformed to a straight shape urged by a top surface of the memory module.

10. The computer of claim 9, wherein the first flap and the second flap are collinear and extend from opposite ends of the valve piece.

11. The computer of claim 8, wherein the first flap has a flake shape.

12. The computer of claim 8, wherein the first flap has a curved shape.

13. The computer of claim 8 further comprising an airduct positioned over the socket and configured to guide air to flow therethrough; the valve piece is attached to an inner side of the airduct.

14. The computer of claim 8, wherein a width of the first flap is larger than a width of a top surface of the memory module.
